(19) United States
(12) Patent Application Publication
(10) Pub. No.: US 2026/0026275 A1
(43) Pub. Date: Jan. 22, 2026

(54) FACET SUPPRESSION FOR EPITAXIAL GROWTH

(71) Applicant: TEXAS INSTRUMENTS INCORPORATED, Dallas, TX (US)

(72) Inventor: Michael Todd, Lehi, UT (US)

(21) Appl. No.: 18/930,106

(22) Filed: Oct. 29, 2024

Related U.S. Application Data
(60) Provisional application No. 63/673,295, filed on Jul. 19, 2024.

(51) Int. Cl. H01L 21/311; H01L 21/762; H01L 27/12

(52) U.S. Cl. CPC H01L 21/31116; H01L 21/76262; H10D 86/201

(57) ABSTRACT

The present disclosure generally relates to semiconductor processing including facet suppression for an epitaxial growth process. In an example, a semiconductor device includes a first semiconductor material, a dielectric layer, and a second semiconductor material. The first semiconductor material includes a monocrystalline surface. The dielectric layer is over the first semiconductor material and has an opening to the first semiconductor material. The opening is defined at least in part by a sidewall of the dielectric layer. The sidewall includes a retrograde sidewall portion. The retrograde sidewall portion is planar and retrograde laterally into the dielectric layer from a distance distal from an interface between the dielectric layer and the monocrystalline surface of the first semiconductor material to a surface of the dielectric layer at the interface. The second semiconductor material is over the first semiconductor material. The second semiconductor material is at least partially in the opening.

### CROSS-REFERENCE TO RELATED APPLICATIONS

This application claims priority to and the benefit of U.S. Provisional Patent Application Ser. No. 63/673,295, filed on Jul. 19, 2024, which is incorporated herein by reference in its entirety.

### BACKGROUND

Epitaxial growth processes are common in semiconductor processing. Epitaxial growth processes may be used to deposit monocrystalline semiconductor material on an underlying monocrystalline material. Epitaxial growth processes can be selective or non-selective. Selective Epitaxial Growth (SEG) occurs when there is growth of epitaxial films on exposed monocrystalline regions on a semiconductor substrate, but no epitaxial growth occurs on other monocrystalline regions on the semiconductor substrate. Non-selective or blanket epitaxial growth processes result in epitaxial film growth on exposed monocrystalline regions of a semiconductor substrate and deposition of non-monocrystalline films (e.g., polycrystalline) on non-monocrystalline surfaces (e.g., polycrystalline or amorphous) of the semiconductor substrate. The epitaxially grown semiconductor material may be integrated in semiconductor devices.

### SUMMARY

An example described herein is a semiconductor device. The semiconductor device includes a first semiconductor material, a dielectric layer, and a second semiconductor material. The first semiconductor material includes a monocrystalline surface. The dielectric layer is over the first semiconductor material. The dielectric layer has an opening to the first semiconductor material. The opening is defined at least in part by a sidewall of the dielectric layer. The sidewall includes a retrograde sidewall portion. The retrograde sidewall portion is planar and retrograde laterally into the dielectric layer from a distance distal from an interface between the dielectric layer and the monocrystalline surface of the first semiconductor material to a surface of the dielectric layer at the interface. The second semiconductor material is over the first semiconductor material. The second semiconductor material is at least partially in the opening through the dielectric layer.

Another example is a method. A dielectric layer is formed over a first semiconductor material. The first semiconductor material includes a monocrystalline surface. An opening is formed through the dielectric layer to the monocrystalline surface. The opening is defined at least in part by a sidewall of the dielectric layer. A vapor phase etch is performed. The vapor phase etch etches the dielectric layer at the sidewall at a surface of the dielectric layer at a first interface between the dielectric layer and the monocrystalline surface of the first semiconductor material. A second semiconductor material is formed over the first semiconductor material and at least partially in the opening through the dielectric layer.

A further example is a semiconductor device The semiconductor device includes a first semiconductor material, a dielectric layer, and a second semiconductor material. The first semiconductor material includes a monocrystalline surface. The dielectric layer is over the first semiconductor material. The dielectric layer has an opening to the first semiconductor material. The opening is to a recess in the first semiconductor material. The recess is through the monocrystalline surface and undercuts the dielectric layer. The second semiconductor material is over the first semiconductor material and in the recess. The second semiconductor material is at least partially in the opening through the dielectric layer.

Another example is a method. A dielectric layer is formed over a first semiconductor material. The first semiconductor material includes a monocrystalline surface. An opening is formed through the dielectric layer to the monocrystalline surface. The opening is defined at least in part by a sidewall of the dielectric layer. A recess is formed in the first semiconductor material through the monocrystalline surface. Forming the recess is through the opening through the dielectric layer. The recess in the first semiconductor material undercuts the dielectric layer. A second semiconductor material is formed over the first semiconductor material. The second semiconductor material is in the recess in the first semiconductor material and at least partially in the opening through the dielectric layer.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1, 2, 3, and 4 are respective cross-sectional views of a semiconductor structure in intermediate stages of a method of manufacturing according to some examples.

FIG. 5 is a cross-sectional view of a semiconductor structure as a modification to the method of manufacturing in FIGS. 1 through 4 according to some examples.

FIGS. 6, 7, 8A, 8B, 8C, and 9 are respective cross-sectional views of a semiconductor structure in intermediate stages of a method of manufacturing according to some examples.

FIGS. 10, 11, and 12 are respective cross-sectional views of a semiconductor structure in intermediate stages of a method of manufacturing according to some examples.

FIG. 13 is a cross-sectional view of a semiconductor structure as a modification to the method of manufacturing in FIGS. 9 through 12 according to some examples.

FIGS. 14, 15, 16, 17, 18, 19, and 20 are respective cross-sectional views of a semiconductor structure in intermediate stages of a method of manufacturing according to some examples.

FIG. 21 is a cross-sectional view of a semiconductor structure as a modification to the method of manufacturing in FIGS. 14 through 20 according to some examples.

FIGS. 22, 23, and 24 are respective cross-sectional views of a semiconductor structure in intermediate stages of a method of manufacturing according to some examples.

FIG. 25 is a cross-sectional view of a semiconductor structure as a modification to the method of manufacturing in FIGS. 22 through 24 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing including facet suppression for an epitaxial growth process. Some examples include a semiconductor device that is formed at least in part by, generally, epitaxially growing a second semiconductor material in an opening through a dielectric structure and on a first semiconductor material. In some examples, a surface of the first semiconductor material that the dielectric structure is on has a (100) surface orientation, and a sidewall(s) of the opening through the dielectric structure has a (110) surface orientation. In some examples, a surface bonding energy gradient is created in a dielectric layer of the dielectric structure, and a vapor phase etch is performed to etch the dielectric layer at an interface between the dielectric layer and the first semiconductor material. In some examples, the first semiconductor material is etched through the opening through the dielectric structure such that the first semiconductor material is undercut under the dielectric structure. By implementing one or both of these mechanisms, the dielectric structure is untemplated from the first semiconductor material, which may permit epitaxial growth of the second semiconductor material that is conformal, defect free, and stacking fault free and that is without faceting within the opening. Various examples may permit lateral and vertical scaling of some devices to smaller dimensions. Additionally, various examples may facilitate scaling of lateral and vertical device dimensions and integrating with other devices, such as complementary metal-oxide-semiconductor (CMOS) devices (e.g., including forming sigma cavities for embedded silicon germanium (SiGe) source/drain enhancements to maximize strain), on the same die without undesirable implications. Other benefits and advantages may be achieved.

Various examples are described subsequently. Although the specific examples may illustrate various aspects of the above generally described features, examples may incorporate any combination of the above generally described features (which are described in more detail in examples below).

Various aspects and components described herein may be integrated into various devices. For example, a semiconductor material that is epitaxially grown as described herein may be implemented as a collector layer or an emitter layer for a bipolar junction transistor (BJT), and more particularly, for a Heterojunction BJT (HBT). Other examples that may incorporate a semiconductor material that is epitaxially grown as described herein may include a micro-electromechanical (MEM) device. Various devices may incorporate an epitaxially grown layer on a semiconductor substrate (e.g., wafer) with a patterned dielectric layer that has sidewall dielectrics, which in some examples, the sidewalls may be a (110) surface orientation on a (100) surface orientation semiconductor substrate (e.g., a Si(100) substrate).

To avoid unnecessary repetition, some concepts that may be common to multiple examples described herein are first described here. In many examples, a second semiconductor material 402 is epitaxially grown on a first semiconductor material 102. The epitaxial growth of the second semiconductor material 402 is through an opening defined through a dielectric structure on and over the first semiconductor material 102. The dielectric structure varies through different examples. The dielectric structure may undergo processing and have a structure that reduces or removes a templating effect.

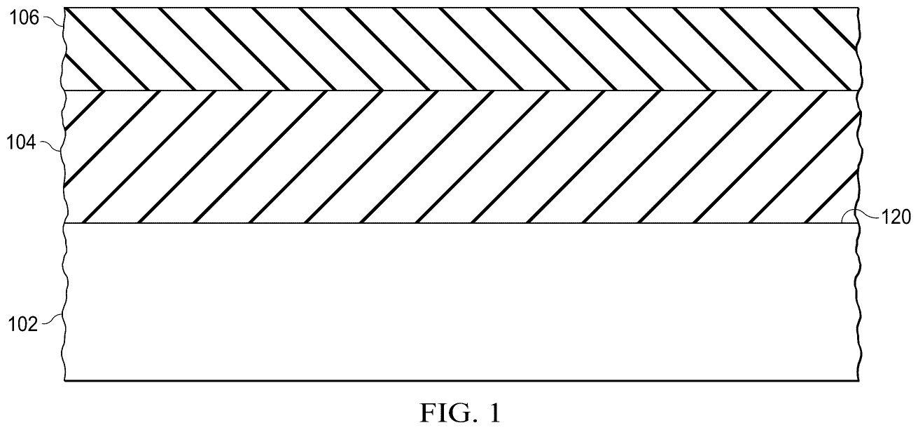

The first semiconductor material 102 is a semiconductor material that is monocrystalline and has a monocrystalline surface 120, which in the illustrated examples is an upper surface of the first semiconductor material 102 (e.g., as shown in FIG. 1). The first semiconductor material 102 may be or be included in a semiconductor substrate. A semiconductor substrate may be or include a bulk semiconductor substrate, a semiconductor-on-insulator (SOI) substrate, or any other appropriate substrate. The semiconductor substrate may also include a support (or handle) substrate and an epitaxial layer epitaxially grown on the support substrate, such that, for example, the first semiconductor material 102 may be the epitaxial layer. In some examples, the semiconductor substrate is or includes a silicon substrate (which may be singulated from a bulk silicon wafer at the conclusion of semiconductor processing). In further examples, the semiconductor substrate includes a silicon substrate with an epitaxial silicon layer grown thereon. In some examples, the semiconductor material is or includes silicon (Si), silicon germanium (SiGe), gallium arsenide (GaAs), gallium nitride (GaN), the like, or a combination thereof. In some examples, the first semiconductor material 102 may be another layer over a semiconductor substrate.

The second semiconductor material 402 is epitaxially grown in the opening through the dielectric structure and on the first semiconductor material 102. In some examples, before the epitaxial growth, a bake process may be performed. The bake process may be at a temperature in a range from 450° C. to 1,000° C. in an environment with a pressure in a range from 1 mTorr to 760 torr and with a flow rate of hydrogen (H₂) gas (e.g., having a high purity) in a range from 1 standard liters per minute (slm) to 200 slm. The bake process may be performed for a duration of 5 seconds to 10 minutes. The bake process may clean and activate the surface of the first semiconductor material 102 exposed through the opening through the dielectric structure for epitaxial growth. The second semiconductor material 402 may be any semiconductor material and may be monocrystalline. The epitaxial growth process may be a chemical vapor deposition (CVD) process, such as a low pressure CVD (LPCVD), reduced pressure CVD (RPCVD), metal organic CVD (MOCVD), or the like. The epitaxial growth process may be at a temperature in a range from 450° C. to 1,000° C. in an environment with a pressure in a range from 1 mTorr to 760 torr. The second semiconductor material 402 may be in situ doped with any appropriate dopant during epitaxial growth. The bake process and epitaxial growth may be performed in a same chamber of a processing tool. Further, the bake process may be isothermal to the epitaxial growth process. The bake process may be preceded by a wet clean, a plasma clean, a remote plasma clean, or any combination thereof.

In some examples, the first semiconductor material 102 is silicon, and the monocrystalline surface 120 is a (100) surface orientation of monocrystalline silicon. In some examples, the second semiconductor material 402 is silicon. Further, the opening through the dielectric structure, in some examples, is defined at least in part by dielectric sidewalls having respective (110) surface orientations.

Examples described herein may implement different mechanisms for reducing or removing a templating effect and for facet suppression during the epitaxial growth of the second semiconductor material 402. Some examples may implement retrograde sidewall portions that define, at least in part, the opening of the dielectric structure in which the second semiconductor material 402 is epitaxially grown. Some examples may implement a recess in the first semiconductor material 102 that undercuts the dielectric structure and extends laterally outside of the opening through the dielectric structure, and the second semiconductor material 402 is epitaxially grown in the recess in the first semiconductor material 102 and in the opening through the dielectric structure. These mechanisms may be implemented in various ways, as described below, and may be implemented together.

During the epitaxial growth process, a growth front of the second semiconductor material 402 does not have a facet (e.g., does not include a (111) facet, a (311) facet, or another facet plane) while the growth front of the second semiconductor material 402 is at or below a level of an upper surface of the dielectric structure present during the epitaxial growth. Hence, if the second semiconductor material 402, as grown, has an upper surface co-planar with or below the upper surface of the dielectric structure, the upper surface of the second semiconductor material 402 does not include a facet in some examples. For example, when the monocrystalline surface 120 of the first semiconductor material 102 is a (100) surface orientation, the upper surface of the second semiconductor material 402, in those situations, would also be a (100) surface orientation, even when, for example, the dielectric sidewalls of the opening have (110) surface orientations.

When the growth front of the second semiconductor material 402 is above the level of the upper surface of the dielectric structure, the growth front of the second semiconductor material 402 may include a facet. The second semiconductor material 402 may grow laterally over the dielectric structure once the growth front is above the level of the upper surface of the dielectric structure. In such examples, the second semiconductor material 402 includes an overgrowth portion over the dielectric structure, which overgrowth portion may have the facet. In some examples, the facet may have a (111) surface orientation, a (311) surface orientation, a combination of (111) and (311) facet planes, or another surface orientation. For example, when the monocrystalline surface 120 is a (100) surface orientation and the dielectric sidewalls of the opening have (110) surface orientations, the upper surface of the second semiconductor material 402 may include a facet with a (111) surface orientation when the second semiconductor material 402 includes an overgrowth portion over the dielectric structure.

FIGS. 1 through 4 are respective cross-sectional views of a semiconductor structure in intermediate stages of a method of manufacturing according to some examples. Referring to FIG. 1, a first dielectric layer 104 is formed over and on the monocrystalline surface 120 of the first semiconductor material 102. The first dielectric layer 104 may be any dielectric material that is capable of having a gradient surface bonding energy, as described in more detail below. The first dielectric layer 104 may be formed or deposited by any appropriate process. In some examples, the first dielectric layer 104 may be or include silicon oxide. In some examples, the first dielectric layer 104 is silicon oxide formed by thermal oxidation, plasma enhanced chemical vapor deposition (PECVD), plasma enhanced atomic layer deposition (PEALD), or the like. In some examples, the first dielectric layer 104 has a thickness in a range from 10 angstroms (Å) to 100 Å.

The second dielectric layer 106 is formed over and on the first dielectric layer 104. The second dielectric layer 106 may be any dielectric material that, in part, creates the gradient surface bonding energy in the first dielectric layer 104. The second dielectric layer 106 may be formed or deposited by any appropriate process. In some examples, the second dielectric layer 106 may be or include silicon nitride. In some examples, the second dielectric layer 106 is silicon nitride formed by PECVD or the like. In some examples, the second dielectric layer 106 has a thickness in a range from 10 Å to 2 μm. One or more additional dielectric layers may be formed over the dielectric layers 104, 106 in some examples.

The surface bonding energy of the first dielectric layer 104 at an interface between the first dielectric layer 104 and the first semiconductor material 102 (e.g., at the monocrystalline surface 120) is different from the surface bonding energy of the first dielectric layer 104 at an interface between the first dielectric layer 104 and the second dielectric layer 106. In some examples, the surface bonding energy of the first dielectric layer 104 at the interface between the first dielectric layer 104 and the first semiconductor material 102 is less than the surface bonding energy of the first dielectric layer 104 at the interface between the first dielectric layer 104 and the second dielectric layer 106. The difference between the surface bonding energies at the interfaces results in a gradient surface bonding energy in the first dielectric layer 104. The gradient surface bonding energy permits etch selectivity in the first dielectric layer 104, as described subsequently.

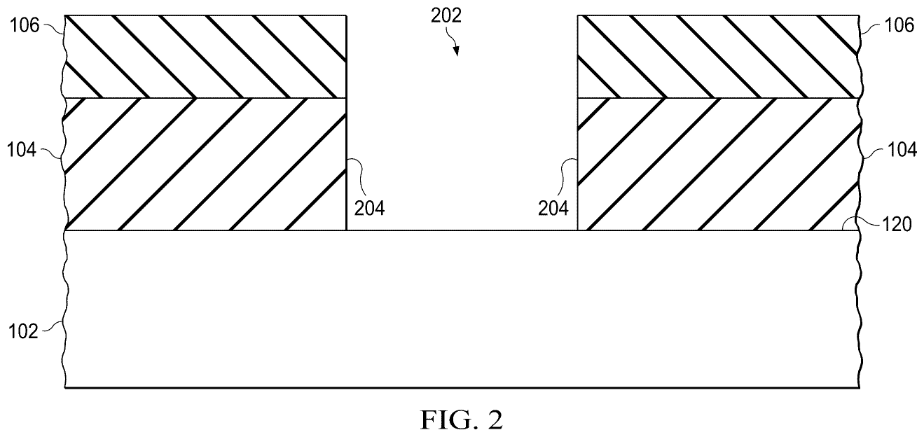

Referring to FIG. 2, an opening 202 is formed through the second dielectric layer 106 and first dielectric layer 104 to the monocrystalline surface 120 of the first semiconductor material 102. The opening 202 may be formed using appropriate photolithography and etch processes. For example, a reactive ion etch (RIE) may be an etch process used to form the opening 202. The RIE may etch through the second dielectric layer 106 and first dielectric layer 104 to the monocrystalline surface 120, which exposes the monocrystalline surface 120 through the opening 202. The opening 202 is defined, at least in part, by dielectric sidewalls 204 of the first dielectric layer 104. In some examples, the dielectric sidewalls 204 have respective (110) surface orientations. A cleaning process may be performed after the photolithography and etch processes. The cleaning process may include any wet clean, such as a sulfuric acid (H₂SO₄) and hydrogen peroxide (H₂O₂) mixture (SPM), an RCA clean (e.g., a standard clean 1 (SC1)), another wet process that removes organic material, or the like. In some examples, a SC1 is used in a cleaning process, which may terminate an exposed portion of the monocrystalline surface 120 with oxygen to form a thin oxide layer (e.g., a monolayer) on the monocrystalline surface 120 exposed through the opening 202. The thin oxide layer may provide a level of protection to the exposed monocrystalline surface 120 between processes (e.g., including during transport between processing tools). In some examples, neither the etch process nor the cleaning process includes using hydrofluoric acid (HF). Using hydrofluoric acid (HF) in, for example, an etch process or cleaning process may create a footing of the first dielectric layer 104 on the monocrystalline surface 120 that extends from a respective dielectric sidewall 204 of the opening 202. Hence, by avoiding using hydrofluoric acid (HF), such a footing may be reduced or avoided.

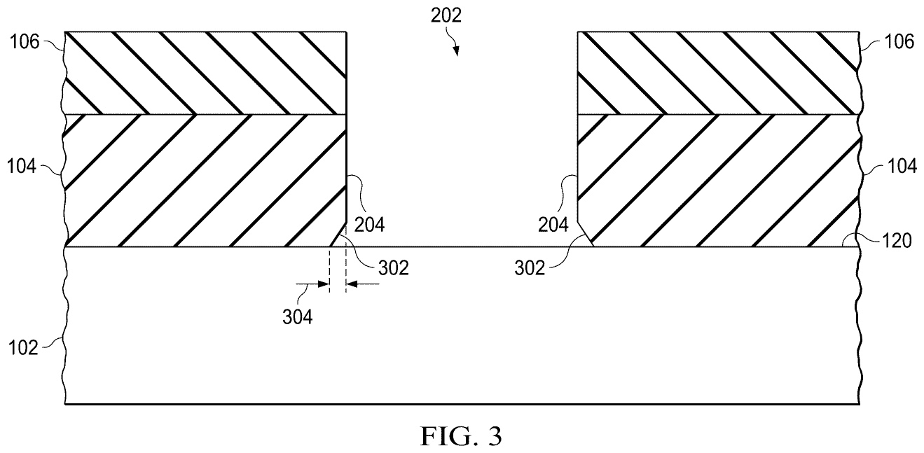

Referring to FIG. 3, a vapor phase etch (VPE) is performed through the opening 202. The VPE selectively etches the first dielectric layer 104 at the interface between the first dielectric layer 104 and the first semiconductor material 102. The VPE may be isotropic or anisotropic. The gradient surface bonding energy permits the VPE to selectively etch the first dielectric layer 104 at the interface between the first dielectric layer 104 and the first semiconductor material 102 at a greater rate than etching the first dielectric layer 104 at the interface between the first dielectric layer 104 and the second dielectric layer 106. The VPE forms respective retrograde sidewall portions 302 in the dielectric sidewalls 204 (e.g., in the first dielectric layer 104) and at the interface between the first dielectric layer 104 and the first semiconductor material 102. Each retrograde sidewall portion 302 is planar and is retrograde laterally into the first dielectric layer 104 relative to a portion of the dielectric sidewall 204 that adjoins the respective retrograde sidewall portion 302. Hence, the retrograde sidewall portion 302 and the adjoining portion of the dielectric sidewall 204 form an angle less than 180° interior to the first dielectric layer 104. More specifically in some examples, each retrograde sidewall portion 302 is retrograde laterally into the first dielectric layer 104 from a distance distal from the interface between the first dielectric layer 104 and the first semiconductor material 102 to that interface (e.g., irrespective of an adjoining portion of the dielectric sidewall 204).

In some examples, the VPE may be a plasma process, such as a remote plasma process. Furthermore, in some examples, the VPE may include flowing a gas mixture including ammonia (NH₃) gas and nitrogen trifluoride (NF₃) gas. The VPE process may be tuned with an endpoint such that oxide on the monocrystalline surface 120 exposed through the opening 202 is removed and the first dielectric layer 104 is etched sufficiently to form the retrograde sidewall portions 302 to a target size. In some examples, although not illustrated, the first dielectric layer 104 may be etched at the dielectric sidewalls 204 such that the first dielectric layer 104 is undercut under the second dielectric layer 106 from an interface between the first dielectric layer 104 and the second dielectric layer 106 to the retrograde sidewall portions 302 (which is referred to as an upper undercut for convenience). The lateral distance of the upper undercut may be up to 200 Å in some examples. In some examples, a distance 304 of a bottom undercut laterally from the adjoining portion of the dielectric sidewall 204 to where the retrograde sidewall portion 302 meets the monocrystalline surface 120 of the first semiconductor material 102 is in a range from 4 Å to 40 Å.

By forming the retrograde sidewall portions 302, a templating effect may be reduced or avoided. In some examples, by removing a portion of the first dielectric layer 104 adjacent to the first semiconductor material 102 by forming the retrograde sidewall portions 302, the templating effect may be reduced or removed at an atomic level. Reducing or removing the templating effect may restore more of the bulk crystal at the surface on which another semiconductor material is epitaxially grown, which may suppress or avoid facet formation.

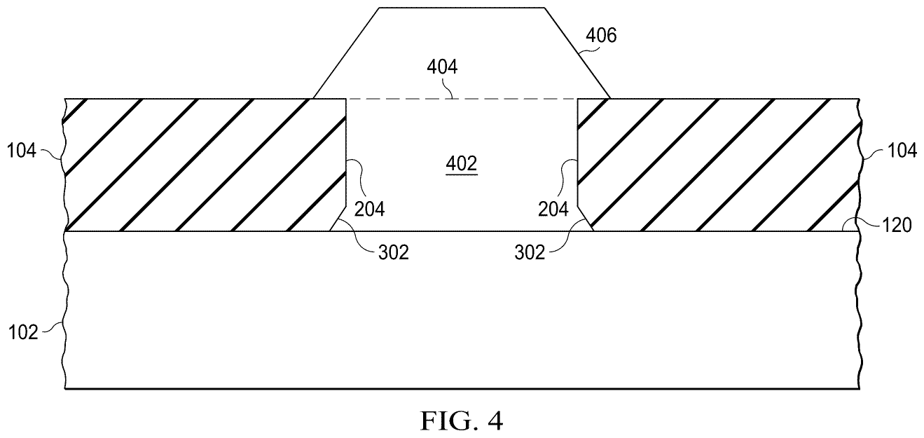

Referring to FIG. 4, the second dielectric layer 106 is removed. The second dielectric layer 106 may be removed by any appropriate process. For example, when the second dielectric layer 106 is silicon nitride, the second dielectric layer 106 may be removed by a phosphoric acid etch or the like. The second semiconductor material 402 is epitaxially grown in the opening 202 and on the first semiconductor material 102 (e.g., on the monocrystalline surface 120), as described above. Before the epitaxial growth, in some examples, a bake process may be performed, as described above.

As described generally previously, in the example of FIG. 4, during the epitaxial growth process, a growth front of the second semiconductor material 402 does not have a facet while the growth front of the second semiconductor material 402 is at or below a level 404 of an upper surface of the first dielectric layer 104. When the growth front of the second semiconductor material 402 is above the level 404 of the upper surface of the first dielectric layer 104, the second semiconductor material 402 may include an overgrowth portion over the first dielectric layer 104, and the growth front of the second semiconductor material 402 may include a facet 406. In a manufactured semiconductor device, the upper surface of the second semiconductor material 402 may be below, at, or above the level 404.

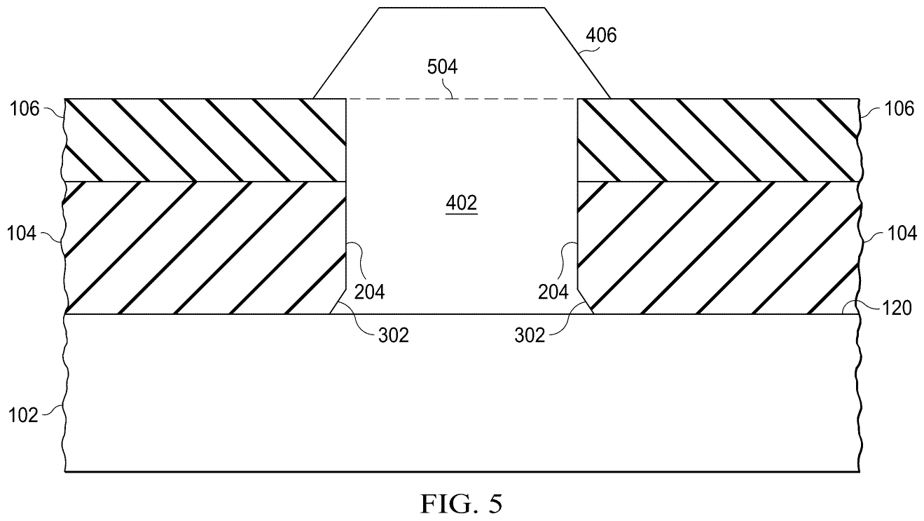

FIG. 5 is a cross-sectional view of a semiconductor structure as a modification to the method of manufacturing in FIGS. 1 through 4 according to some examples. In FIG. 5, the epitaxial growth process to form the second semiconductor material 402 is performed with the second dielectric layer 106 present. For example, the second dielectric layer 106 is not removed prior to the epitaxial growth process. The bake process and epitaxial growth process may be performed as described above.

In the example of FIG. 5, during the epitaxial growth process, a growth front of the second semiconductor material 402 does not have a facet while the growth front of the second semiconductor material 402 is at or below a level 504 of an upper surface of the second dielectric layer 106. When the growth front of the second semiconductor material 402 is above the level 504 of the upper surface of the second dielectric layer 106, the second semiconductor material 402 may include an overgrowth portion over the second dielectric layer 106, and the growth front of the second semiconductor material 402 may include a facet 406. In a manufactured semiconductor device, the upper surface of the second semiconductor material 402 may be below, at, or above the level 504.

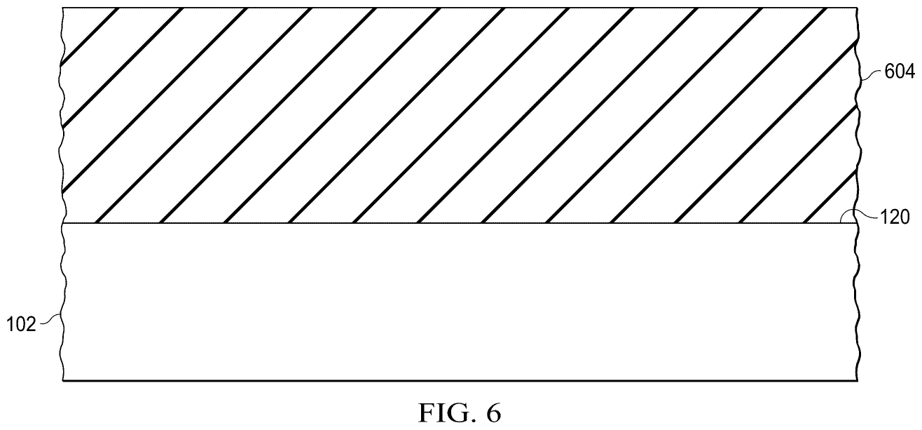

FIGS. 6 through 9 are respective cross-sectional views of a semiconductor structure in intermediate stages of a method of manufacturing according to some examples. Referring to FIG. 6, a dielectric layer 604 is formed over and on the monocrystalline surface 120 of the first semiconductor material 102. The dielectric layer 604 may be any dielectric material. The dielectric layer 604 may be formed or deposited by any appropriate process. In some examples, the dielectric layer 604 may be or include silicon oxide. In some examples, the dielectric layer 604 is silicon oxide formed by thermal oxidation, PECVD, PEALD, or the like. In some examples, the dielectric layer 604 has a thickness in a range from 20 Å to 2 μm.

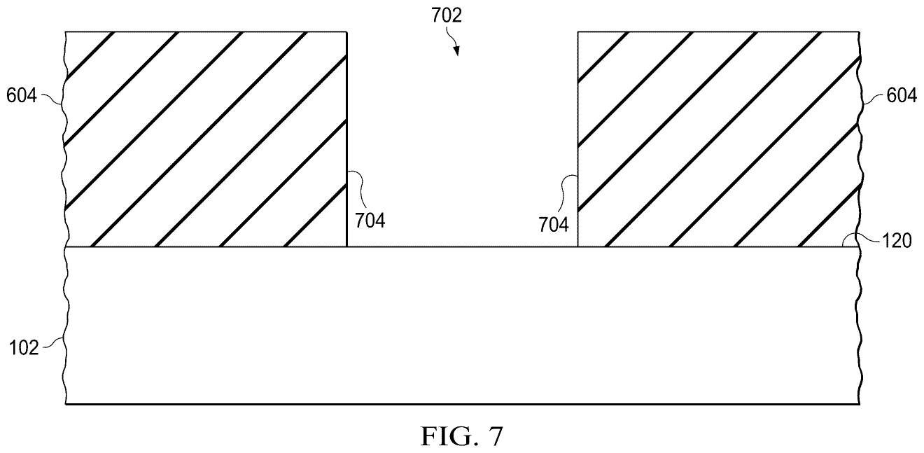

Referring to FIG. 7, an opening 702 is formed through the dielectric layer 604 to the monocrystalline surface 120 of the first semiconductor material 102. The opening 702 may be formed using appropriate photolithography and etch processes. For example, a RIE may be an etch process used to form the opening 702. The RIE may etch through the dielectric layer 604 to the monocrystalline surface 120, which exposes the monocrystalline surface 120 through the opening 702. The opening 702 is defined, at least in part, by dielectric sidewalls 704 of the dielectric layer 604. In some examples, the dielectric sidewalls 704 have respective (110) surface orientations. A cleaning process may be performed after the photolithography and etch processes. The cleaning process may include any wet clean, such as a SPM, an RCA clean (e.g., a SC1), another wet process that removes organic material, or the like. In some examples, a SC1 is used in a cleaning process, which may terminate an exposed portion of the monocrystalline surface 120 with oxygen to form a thin oxide layer (e.g., a monolayer) on the monocrystalline surface 120 exposed through the opening 702. The thin oxide layer may provide a level of protection to the exposed monocrystalline surface 120 between processes (e.g., including during transport between processing tools). In some examples, neither the etch process nor the cleaning process includes using hydrofluoric acid (HF), as described above.

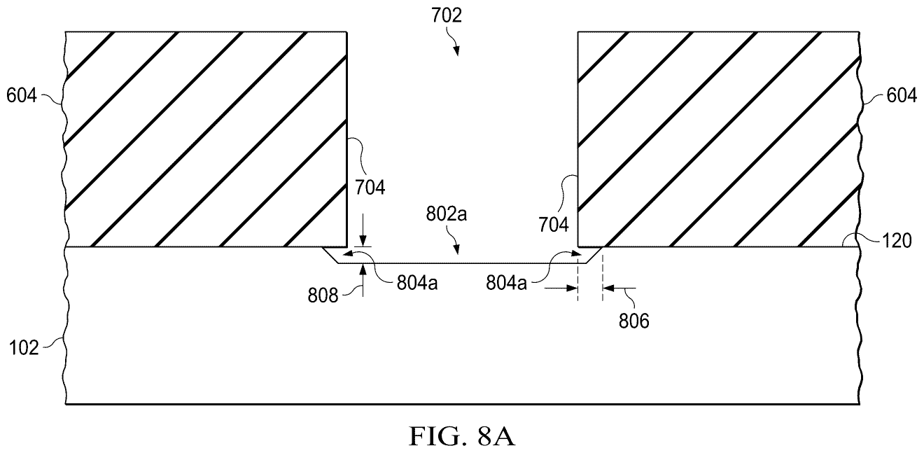

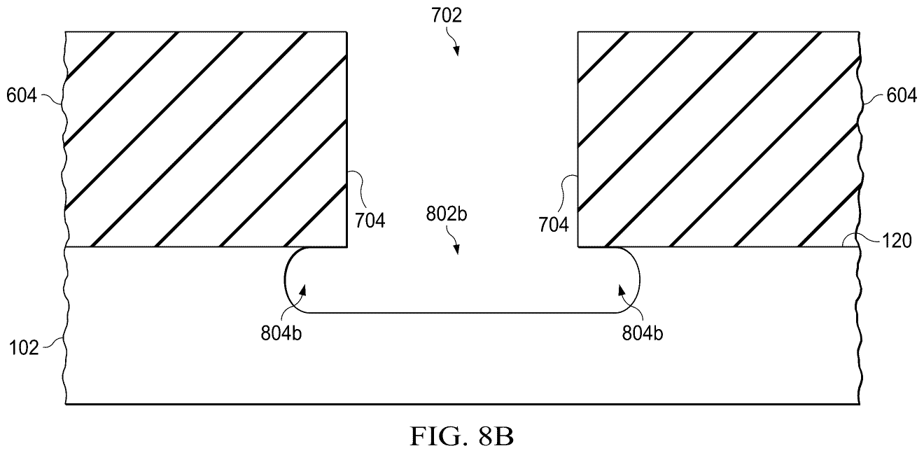

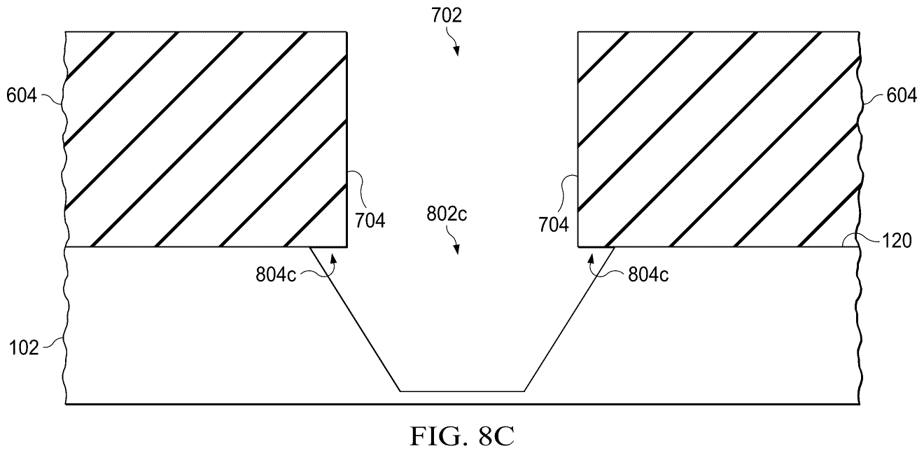

Referring to FIGS. 8A, 8B, and 8C, a recess 802a, 802b, 802c (generally referred to as a recess 802) is formed through the monocrystalline surface 120 and in the first semiconductor material 102. The recess 802 is formed corresponding to the opening 702 through the dielectric layer 604 and extending laterally outside of the opening 702 and under the dielectric layer 604. The recess 802a, 802b, 802c creates undercuts 804a, 804b, 804c (generally undercuts 804) underneath the dielectric layer 604. The recess 802 may be formed using an etch process selective to the first semiconductor material 102. The etch process may be a wet etch process or a dry etch process (e.g., a thermal etch process or a plasma etch process). The etch process may further be isotropic or anisotropic. The etch process, whether isotropic or anisotropic, includes a lateral etching component. FIGS. 8A, 8B, and 8C illustrate how different recess 802a, 802b, 802c, with respective recess profiles, may be formed using different processing.

Referring to FIG. 8A, the recess 802a is formed. The recess 802a creates undercut 804a underneath the dielectric layer 604 laterally outside of the opening 702 through the dielectric layer 604. The recess 802a is formed using a dry thermal etch process (e.g., without a plasma). The dry thermal etch process may be anisotropic. The dry thermal etch process may have a lateral etch rate of the first semiconductor material 102 that is greater than a vertical etch rate of the first semiconductor material 102. In examples where the first semiconductor material 102 is silicon, the dry thermal etch may use a halogen-containing gas (e.g., chlorine (Cl₂) gas, bromine (Br₂), etc.), a hydro-halogen gas (e.g., hydrochloric (HCl) acid, hydrobromic (HBr) acid, etc.), or a combination thereof.

In some examples, a dry cleaning process and a bake process are performed before the dry thermal etch process. In some examples, the dry cleaning process includes flowing a gas mixture including ammonia (NH₃) gas and nitrogen trifluoride (NF₃) gas. The dry cleaning process may be tuned with an endpoint such that any oxide on the monocrystalline surface 120 exposed through the opening 702 is removed. After the dry cleaning process, the bake process may be performed. The bake process may be as described above. After the bake process, the dry thermal etch process may be performed. In some examples, such as when the first semiconductor material 102 is silicon, the dry thermal etch process uses an etchant including hydrochloric (HCl) gas. The dry thermal etch process may be in an environment with a pressure in a range from 1 mTorr to 760 torr and with a gas mixture flowing. The gas mixture may include hydrogen (H₂) gas and hydrochloric (HCl) gas. A flow rate of hydrogen (H₂) gas may be in a range from 1 slm to 200 slm, and a flow rate of hydrochloric (HCl) gas may be in a range from 50 standard cubic centimeters per minute (sccm) to 10 standard liters per minute (slm). The dry thermal etch process may be at a temperature in a range from 750° C. to 1,000° C. The dry thermal etch process may be performed for a duration of 10 seconds to 10 minutes. In some examples, a lateral undercut distance 806 (e.g., laterally from the dielectric sidewall 704) of the undercut 804a of the recess 802a is in a range from 3 Å to 200 Å, and a depth 808 of the recess 802 is in a range from 10 Å to 500 Å. In some examples, the bake process, the dry thermal etch process, and the epitaxial growth process (described subsequently) are performed in a same processing chamber. Further, the bake process, the dry thermal etch process, and the epitaxial growth process may be isothermal. In further examples, the dry cleaning process may be performed in a processing chamber that is included in a same cluster tool as the process chamber in which the bake process, the dry thermal etch process, and the epitaxial growth process are performed. In such examples, an environment in which the first semiconductor material 102 (e.g., substrate or wafer) is disposed is not broken (e.g., maintained) between the processes.

Referring to FIG. 8B, the recess 802b is formed. The recess 802b creates undercut 804b underneath the dielectric layer 604 laterally outside of the opening 702 through the dielectric layer 604. The recess 802b is formed using a dry plasma etch process. The dry plasma etch process may be isotropic (e.g., having equal lateral and vertical etch rates of the first semiconductor material 102). In examples where the first semiconductor material 102 is silicon, the dry plasma etch may use a halogen-containing gas, a hydro-halogen gas, or a combination thereof.

Referring to FIG. 8C, the recess 802c is formed. The recess 802c creates undercut 804c underneath the dielectric layer 604 laterally outside of the opening 702 through the dielectric layer 604. The recess 802c is formed using a wet etch process. The wet etch process may be isotropic or, as illustrated, anisotropic. For example, the wet etch process may be anisotropic by selectively etching crystalline planes of the first semiconductor material 102, such as illustrated in FIG. 8C. In examples where the first semiconductor material 102 is silicon, the wet etch process may use a halogen-containing liquid, a hydro-halogen liquid, a combination thereof, or a basic etchant (tetramethylammonium hydroxide (TMAH), sodium hydroxide (NaOH), potassium hydroxide (KOH), or the like).

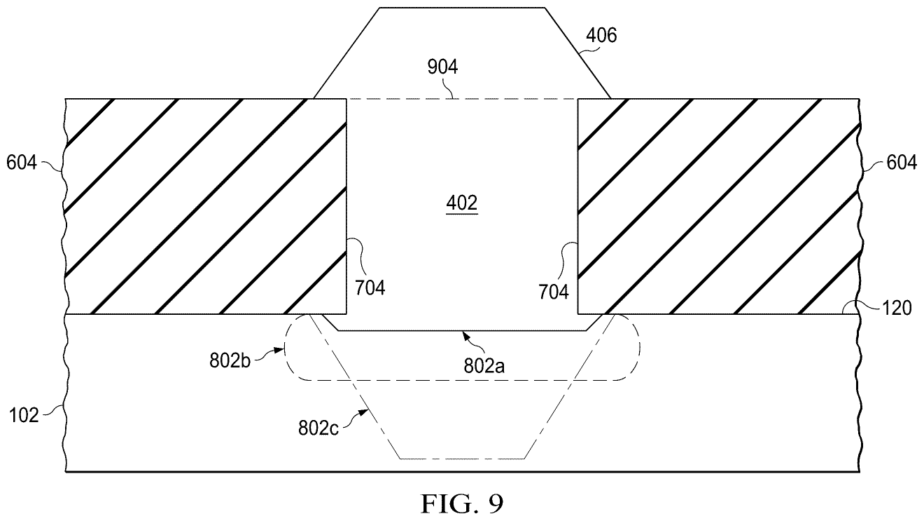

Referring to FIG. 9, a second semiconductor material 402 is epitaxially grown in the recess 802 and the opening 702 and on the first semiconductor material 102, as described above. The different profiles of the recesses 802b, 802c are shown in FIG. 9, although an example where the recess 802a is used is illustrated. The second semiconductor material 402 may fill the undercuts 804 formed by the recess 802.

As described generally previously, in the example of FIG. 9, during the epitaxial growth process, a growth front of the second semiconductor material 402 does not have a facet while the growth front of the second semiconductor material 402 is at or below a level 904 of an upper surface of the dielectric layer 604. When the growth front of the second semiconductor material 402 is above the level 904 of the upper surface of the dielectric layer 604, the second semiconductor material 402 may include an overgrowth portion over the dielectric layer 604, and the growth front of the second semiconductor material 402 may include a facet 406. In a manufactured semiconductor device, the upper surface of the second semiconductor material 402 may be below, at, or above the level 904.

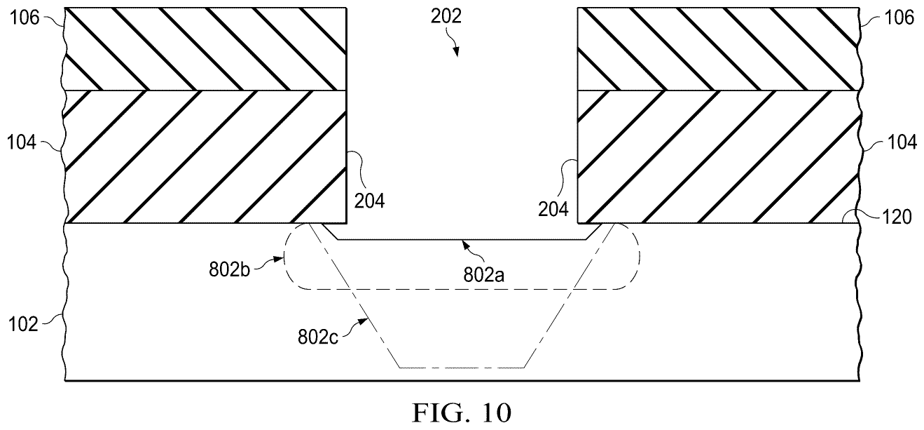

FIGS. 10 through 12 are respective cross-sectional views of a semiconductor structure in intermediate stages of a method of manufacturing according to some examples. Processing proceeds as described above with respect to FIGS. 1 and 2 above. Generally, a first dielectric layer 104 is formed over a first semiconductor material 102, and a second dielectric layer 106 is formed over the first dielectric layer 104. An opening 202 is formed through the second dielectric layer 106 and first dielectric layer 104 to the monocrystalline surface 120 of the first semiconductor material 102. The opening 202 may be formed using appropriate photolithography and etch processes. A cleaning process may be performed after the photolithography and etch processes.

Referring to FIG. 10, a recess 802a, 802b, 802c (generally referred to as recess 802) is formed through the monocrystalline surface 120 and in the first semiconductor material 102. The recess 802 is formed corresponding to the opening 202 through the second dielectric layer 106 and first dielectric layer 104 and extending laterally outside of the opening 202 and under the first dielectric layer 104. The recess 802 may be formed using an etch process as described above with respect to FIGS. 8A, 8B, and 8C. A dry cleaning process may be performed before forming the recess 802.

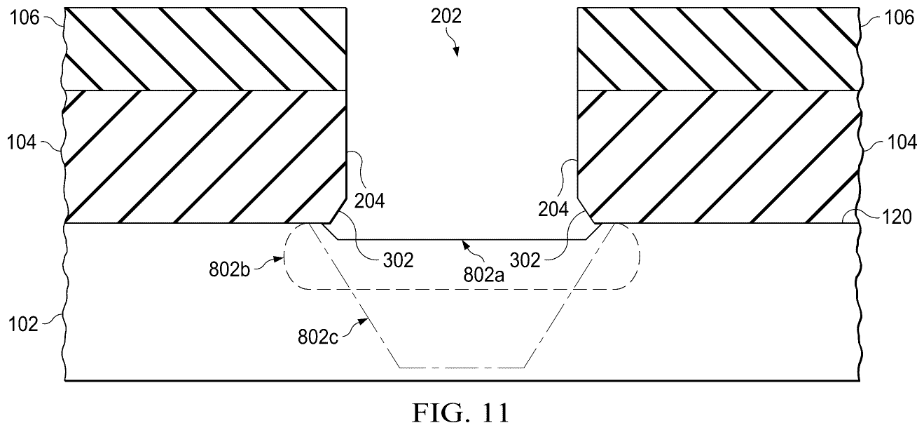

Referring to FIG. 11, a VPE is performed through the opening 202 as described above with respect to FIG. 3. The VPE selectively etches the first dielectric layer 104 at a lower surface of the first dielectric layer 104, which is at the interface between the first dielectric layer 104 and the first semiconductor material 102. The gradient surface bonding energy permits the VPE to selectively etch the first dielectric layer 104 at the lower surface of the first dielectric layer 104 at a greater rate than etching the first dielectric layer 104 at the interface between the first dielectric layer 104 and the second dielectric layer 106. The VPE forms respective retrograde sidewall portions 302 in the dielectric sidewalls 204 (e.g., in the first dielectric layer 104) and at the lower surface of the first dielectric layer 104. Each retrograde sidewall portion 302 may be as described above with respect to FIG. 3.

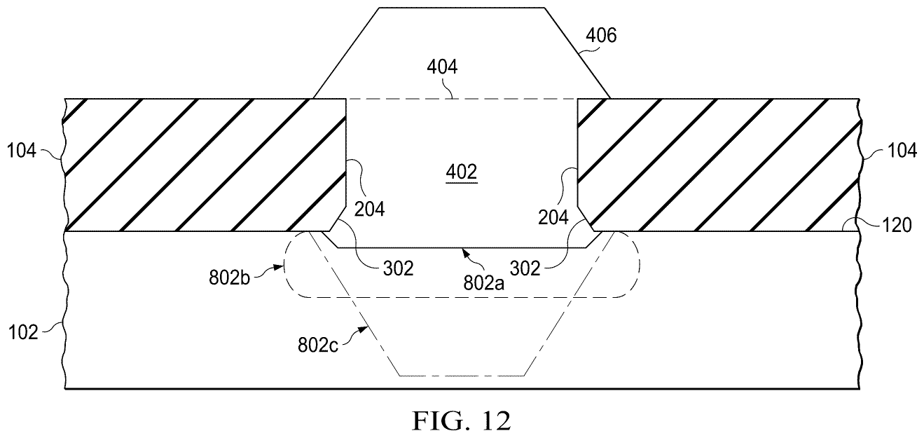

Referring to FIG. 12, the second dielectric layer 106 is removed. The second dielectric layer 106 may be removed by any appropriate process, like described above with respect to FIG. 4. A second semiconductor material 402 is epitaxially grown in the opening 202 and the recess 802 and on the first semiconductor material 102. Before the epitaxial growth, in some examples, a bake process may be performed, like described above.

As described generally previously, in the example of FIG. 12, during the epitaxial growth process, a growth front of the second semiconductor material 402 does not have a facet while the growth front of the second semiconductor material 402 is at or below a level 404 of an upper surface of the first dielectric layer 104. When the growth front of the second semiconductor material 402 is above the level 404 of the upper surface of the first dielectric layer 104, the second semiconductor material 402 may include an overgrowth portion over the first dielectric layer 104, and the growth front of the second semiconductor material 402 may include a facet 406. In a manufactured semiconductor device, the upper surface of the second semiconductor material 402 may be below, at, or above the level 404.

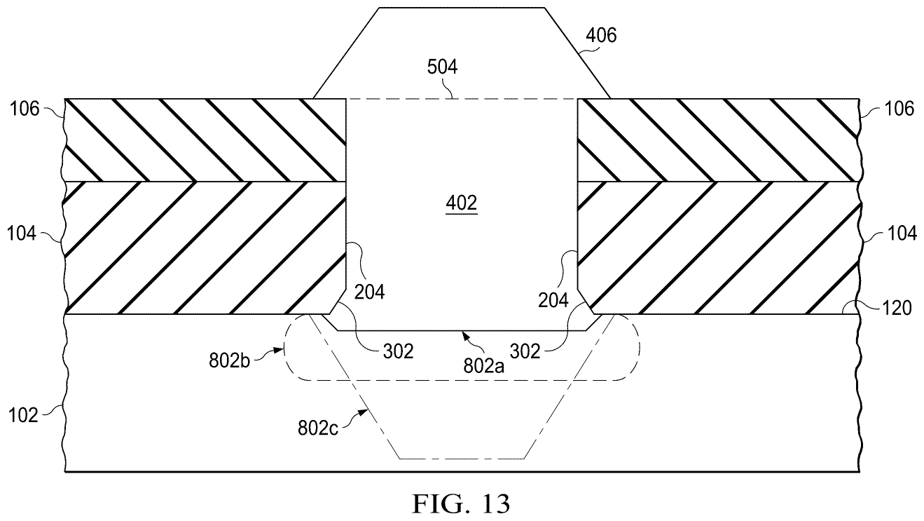

FIG. 13 is a cross-sectional view of a semiconductor structure as a modification to the method of manufacturing in FIGS. 9 through 12 according to some examples. In FIG. 13, the epitaxial growth process to form the second semiconductor material 402 is performed with the second dielectric layer 106 present. For example, the second dielectric layer 106 is not removed prior to the epitaxial growth process. The bake process and epitaxial growth process may be performed as described with respect to FIG. 12.

In the example of FIG. 13, during the epitaxial growth process, a growth front of the second semiconductor material 402 does not have a facet while the growth front of the second semiconductor material 402 is at or below a level 504 of an upper surface of the second dielectric layer 106. When the growth front of the second semiconductor material 402 is above the level 504 of the upper surface of the second dielectric layer 106, the second semiconductor material 402 may include an overgrowth portion over the second dielectric layer 106, and the growth front of the second semiconductor material 402 may include a facet 406. In a manufactured semiconductor device, the upper surface of the second semiconductor material 402 may be below, at, or above the level 504.

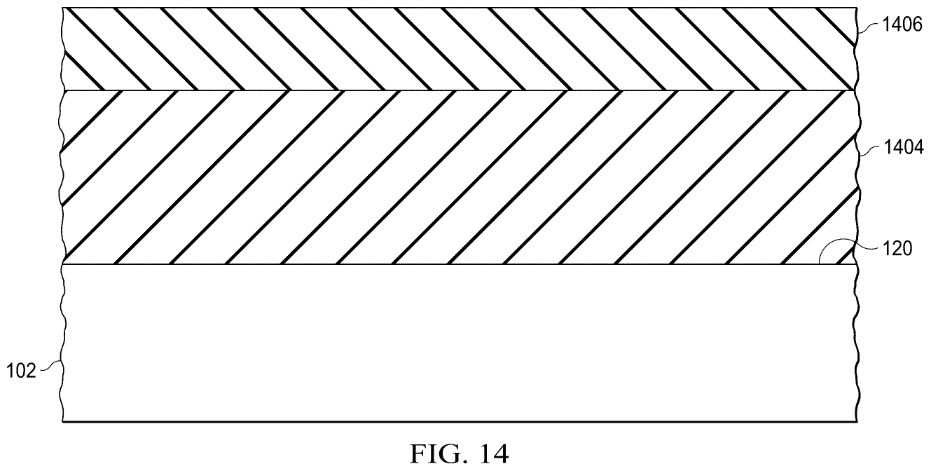

FIGS. 14 through 20 are respective cross-sectional views of a semiconductor structure in intermediate stages of a method of manufacturing according to some examples. Referring to FIG. 14, a first dielectric layer 1404 is formed over and on the monocrystalline surface 120 of the first semiconductor material 102, and a second dielectric layer 1406 is formed over the first dielectric layer 1404. The first dielectric layer 1404 may be any dielectric material that is capable of having a gradient surface bonding energy, as described in more detail below. The first dielectric layer 1404 may be formed or deposited by any appropriate process. In some examples, the first dielectric layer 1404 may be or include silicon oxide. In some examples, the first dielectric layer 1404 is silicon oxide formed by thermal oxidation, PECVD, PEALD, or the like. The second dielectric layer 1406 may be any dielectric material that may provide etch selectivity, such as a hardmask dielectric layer. The second dielectric layer 1406 may be formed or deposited by any appropriate process. In some examples, the second dielectric layer 1406 may be or include silicon nitride. In some examples, the second dielectric layer 1406 is silicon nitride formed by PECVD or the like. One or more additional dielectric layers may be formed over the dielectric layers 1404, 1406 in some examples.

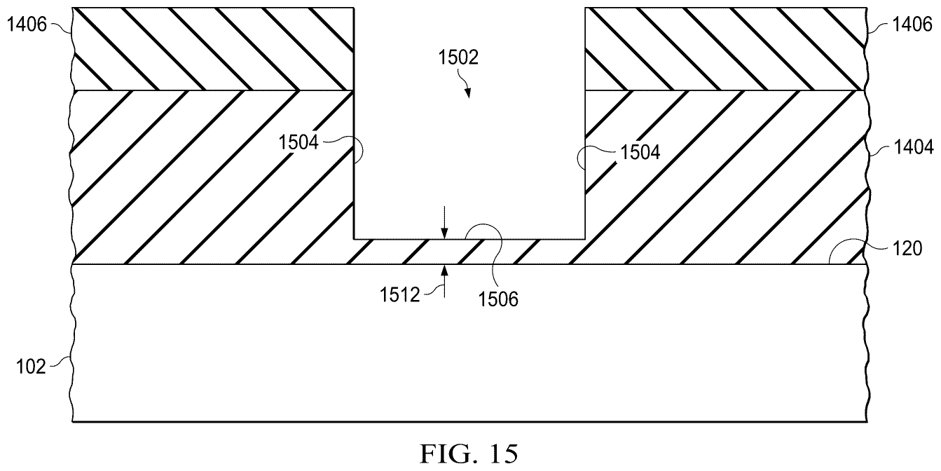

Referring to FIG. 15, a recess 1502 is formed in the first dielectric layer 1404. The recess 1502 is also formed through the second dielectric layer 1406. The recess 1502 in the first dielectric layer 1404 is defined, at least in part, by recess dielectric sidewalls 1504 and a recess bottom surface 1506 of the first dielectric layer 1404. The recess 1502 may be formed using appropriate photolithography and etch processes. For example, an RIE may be an etch process used to form the recess 1502. The RIE may etch through the second dielectric layer 1406 and into the first dielectric layer 1404. In some examples, the recess dielectric sidewalls 1504 have respective (110) surface orientations. A cleaning process may be performed after the photolithography and etch processes. The cleaning process may include any wet clean, such as a SPM, an RCA clean (e.g., a SC1), another wet process that removes organic material, or the like. In some examples, neither the etch process nor the cleaning process includes using hydrofluoric acid (HF). A portion of the first dielectric layer 1404 having a thickness 1512 remains between the recess bottom surface 1506 of the recess 1502 and the monocrystalline surface 120 of the first semiconductor material 102. In some examples, the thickness 1512 may be thin. For example, the thickness 1512 may be in a range from 20 Angstroms to 100 Angstroms.

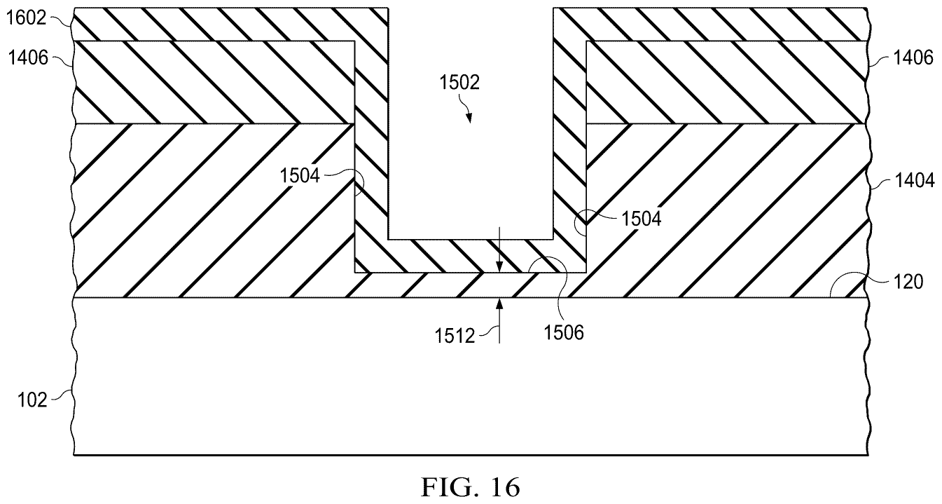

Referring to FIG. 16, a third dielectric layer 1602 is formed conformally in the recess 1502. The third dielectric layer 1602 is formed conformally on and along the recess dielectric sidewalls 1504 and the recess bottom surface 1506. The third dielectric layer 1602 is also formed over the second dielectric layer 1406, as illustrated. The third dielectric layer 1602 may be any dielectric material that, in part, creates the gradient surface bonding energy in the first dielectric layer 1404. The third dielectric layer 1602 may be formed or deposited by any appropriate process. In some examples, the third dielectric layer 1602 may be or include silicon nitride. In some examples, the third dielectric layer 1602 is silicon nitride formed by PECVD or the like. In some examples, the third dielectric layer 1602 has a thickness in a range from 10 Å to 100 Å.

The surface bonding energy of the first dielectric layer 1404 at an interface between the first dielectric layer 1404 and the first semiconductor material 102 (e.g., at the monocrystalline surface 120) is different from the surface bonding energy of the first dielectric layer 1404 at an interface between the first dielectric layer 1404 and the third dielectric layer 1602. In some examples, the surface bonding energy of the first dielectric layer 1404 at the interface between the first dielectric layer 1404 and the first semiconductor material 102 is less than the surface bonding energy of the first dielectric layer 1404 at the interface between the first dielectric layer 1404 and the third dielectric layer 1602. The difference between the surface bonding energies at the interfaces results in a gradient surface bonding energy in the first dielectric layer 1404. The gradient surface bonding energy permits etch selectivity in the first dielectric layer 1404, as described subsequently.

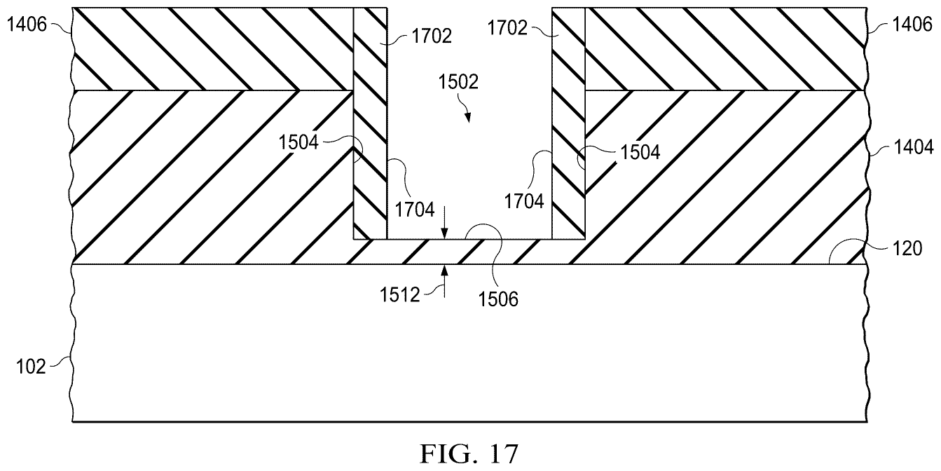

Referring to FIG. 17, dielectric spacers 1702 are formed from the third dielectric layer 1602 along the recess dielectric sidewalls 1504. The third dielectric layer 1602 is anisotropically etched, such as by an RIE, to remove horizontal portions of the third dielectric layer 1602 while vertical portions of the third dielectric layer 1602 remain as the dielectric spacers 1702. Removal of the horizontal portion of the third dielectric layer 1602 along the recess bottom surface 1506 exposes a portion of the recess bottom surface 1506. The dielectric spacers 1702 have respective dielectric sidewalls 1704 opposite from the recess dielectric sidewalls 1504.

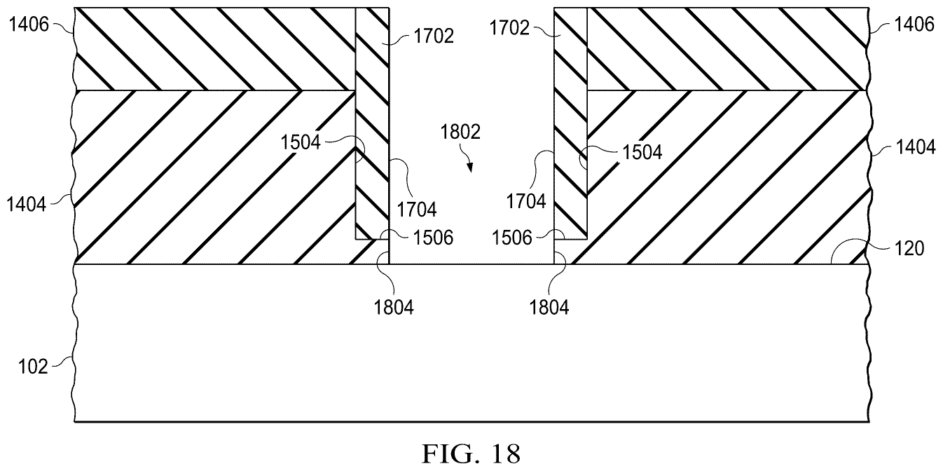

Referring to FIG. 18, an opening 1802 is formed through the first dielectric layer 1404 to the monocrystalline surface 120 of the first semiconductor material 102. The opening 1802 may be formed using appropriate photolithography and etch processes. For example, an RIE may be an etch process used to form the opening 1802. The RIE may etch through the first dielectric layer 1404 exposed at the recess bottom surface 1506 to the monocrystalline surface 120, which exposes the monocrystalline surface 120 through the opening 1802. The opening 1802 is defined, at least in part, by dielectric sidewalls 1804 of the first dielectric layer 1404 and the corresponding dielectric sidewalls 1704 of the dielectric spacers 1702. In some examples, the dielectric sidewalls 1804, 1704 have respective (110) surface orientations. A cleaning process may be performed after the photolithography and etch processes. The cleaning process may include any wet clean, such as a SPM, an RCA clean (e.g., a SC1), another wet process that removes organic material, or the like. In some examples, a SC1 is used in a cleaning process, which may terminate an exposed portion of the monocrystalline surface 120 with oxygen to form a thin oxide layer (e.g., a monolayer) on the monocrystalline surface 120 exposed through the opening 1802. The thin oxide layer may provide a level of protection to the exposed monocrystalline surface 120 between processes (e.g., including during transport between processing tools). In some examples, neither the etch process nor the cleaning process includes using hydrofluoric acid (HF).

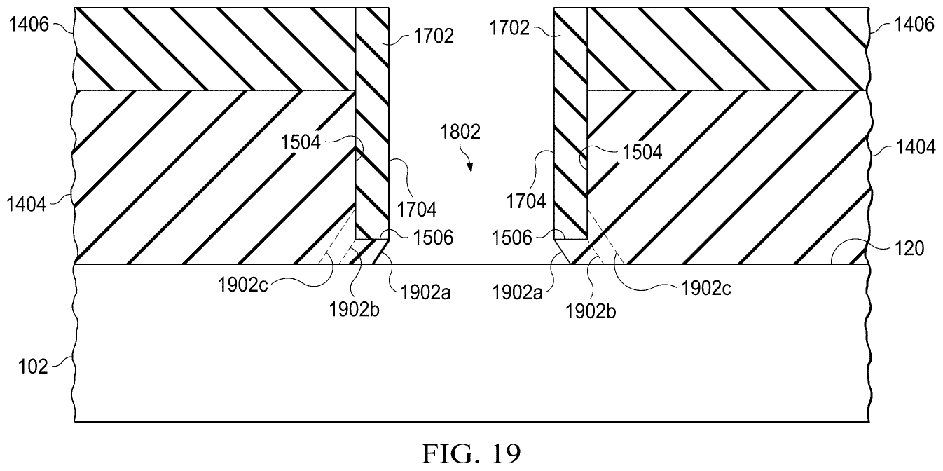

Referring to FIG. 19, a VPE is performed through the opening 1802. The VPE selectively etches the first dielectric layer 1404 at the interface between the first dielectric layer 1404 and the first semiconductor material 102. The VPE may be anisotropic. The gradient surface bonding energy permits the VPE to selectively etch the first dielectric layer 1404 at the interface between the first dielectric layer 1404 and the first semiconductor material 102 at a greater rate than etching the first dielectric layer 1404 at the interface between the first dielectric layer 1404 and the dielectric spacers 1702 (e.g., at the recess bottom surface 1506). The VPE forms respective retrograde sidewall portions 1902a in the first dielectric layer 1404 and at the interface between the first dielectric layer 1404 and the first semiconductor material 102. Depending on a duration of the VPE, the VPE may form the retrograde sidewall portions 1902a (as illustrated), retrograde sidewall portions 1902b, retrograde sidewall portions 1902c (generally referred to as retrograde sidewall portions 1902), or retrograde sidewall portions at any position therebetween, for example. The retrograde sidewall portion 1902a may be formed extending from a bottom surface of a respective dielectric spacer 1702 at the respective dielectric sidewall 1704 of the dielectric spacer 1702. The retrograde sidewall portion 1902b may be formed extending from a bottom surface of a respective dielectric spacer 1702 at the recess dielectric sidewall 1504. The retrograde sidewall portion 1902c may be formed extending from the recess dielectric sidewall 1504. Each retrograde sidewall portion 1902 is planar and is retrograde laterally into the first dielectric layer 1404 from a distance distal from the interface between the first dielectric layer 1404 and the first semiconductor material 102 to that interface.

In some examples, the VPE may be a plasma process, such as a remote plasma process. Furthermore, in some examples, the VPE may include flowing a gas mixture including ammonia (NH₃) gas and nitrogen trifluoride (NF₃) gas. The VPE process may be tuned with an endpoint such that oxide on the monocrystalline surface 120 exposed through the opening 1802 is removed and the first dielectric layer 1404 is etched sufficiently to form the retrograde sidewall portions 1902 to a target position and/or size. The dielectric spacers 1702 may protect any other dielectric layer in the dielectric stack (e.g., between the first dielectric layer 1404 and the second dielectric layer 1406 and/or over the second dielectric layer 1406) from being etched during the VPE.

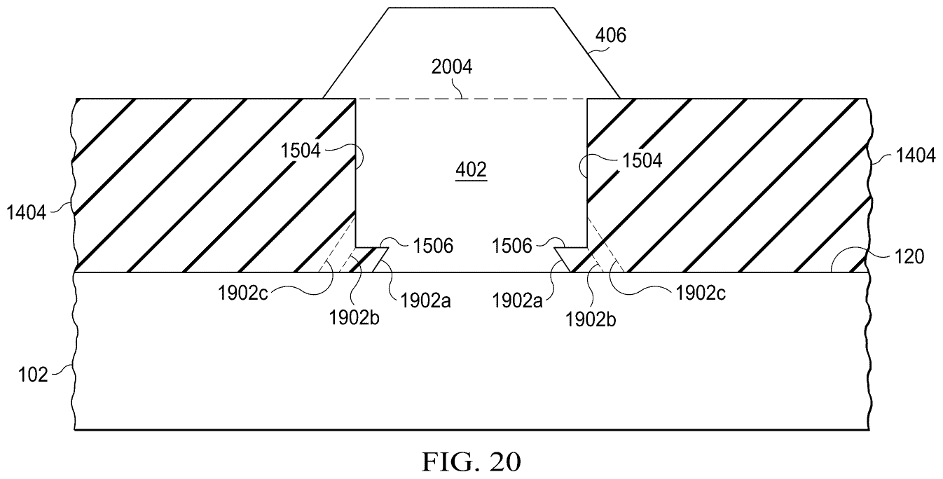

Referring to FIG. 20, the second dielectric layer 1406 and dielectric spacers 1702 are removed. The second dielectric layer 1406 and dielectric spacers 1702 may be removed by any appropriate process. For example, when the second dielectric layer 1406 and dielectric spacers 1702 are silicon nitride, the second dielectric layer 1406 and dielectric spacers 1702 may be removed by a phosphoric acid etch or the like. The second semiconductor material 402 is epitaxially grown in the opening through the first dielectric layer 1404 and on the first semiconductor material 102, as described above. With the removal of the second dielectric layer 1406 and the dielectric spacers 1702, the opening in which the second semiconductor material 402 is epitaxially grown is defined, at least in part, by the recess dielectric sidewalls 1504, any remaining recess bottom surface 1506, and the retrograde sidewall portions 1902. According to some examples, a thickness of the third dielectric layer 1602, and hence, lateral thickness of the dielectric spacers 1702, may be small such that any remaining recess bottom surface 1506 is small and no facets are formed while a growth front is in the opening. Before the epitaxial growth, in some examples, a bake process may be performed, as described above.

As described generally previously, in the example of FIG. 20, during the epitaxial growth process, a growth front of the second semiconductor material 402 does not have a facet while the growth front of the second semiconductor material 402 is at or below a level 2004 of an upper surface of the first dielectric layer 1404. When the growth front of the second semiconductor material 402 is above the level 2004 of the upper surface of the first dielectric layer 1404, the second semiconductor material 402 may include an overgrowth portion over the first dielectric layer 1404, and the growth front of the second semiconductor material 402 may include a facet 406. In a manufactured semiconductor device, the upper surface of the second semiconductor material 402 may be below, at, or above the level 2004.

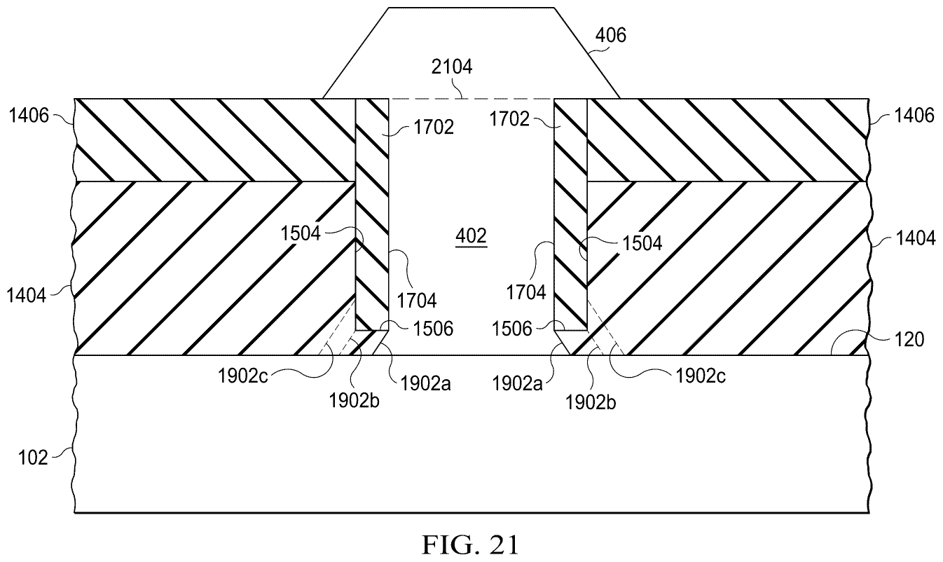

FIG. 21 is a cross-sectional view of a semiconductor structure as a modification to the method of manufacturing in FIGS. 14 through 20 according to some examples. In FIG. 21, the epitaxial growth process to form the second semiconductor material 402 is performed with the second dielectric layer 1406 and dielectric spacers 1702 present. For example, the second dielectric layer 1406 and dielectric spacers 1702 are not removed prior to the epitaxial growth process. The opening in which the second semiconductor material 402 is epitaxially grown is defined, at least in part, by the dielectric sidewalls 1704 of the dielectric spacers 1702 and the retrograde sidewall portions 1902. The bake process and epitaxial growth process may be performed as described above.

In the example of FIG. 21, during the epitaxial growth process, a growth front of the second semiconductor material 402 does not have a facet while the growth front of the second semiconductor material 402 is at or below a level 2104 of an upper surface of the dielectric spacers 1702. When the growth front of the second semiconductor material 402 is above the level 2104 of the upper surface of the dielectric spacers 1702, the second semiconductor material 402 may include an overgrowth portion over the dielectric spacers 1702, and the growth front of the second semiconductor material 402 may include a facet 406. In a manufactured semiconductor device, the upper surface of the second semiconductor material 402 may be below, at, or above the level 2104.

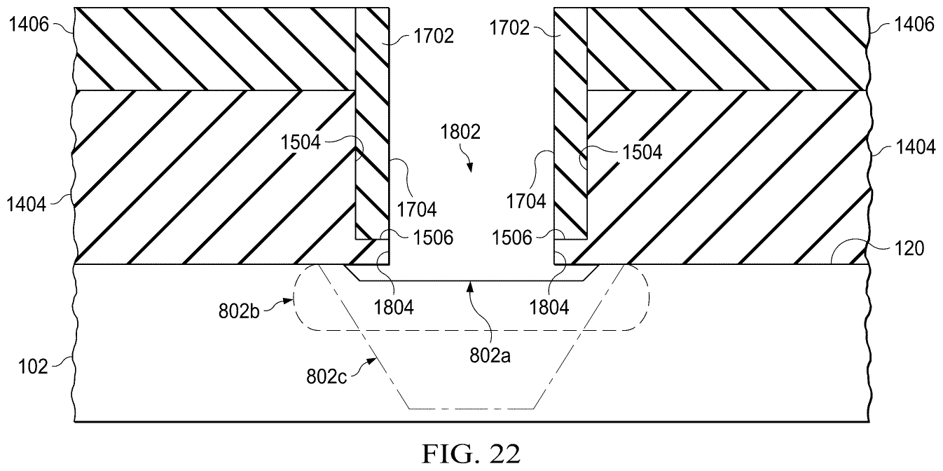

FIGS. 22 through 24 are respective cross-sectional views of a semiconductor structure in intermediate stages of a method of manufacturing according to some examples. Processing proceeds as described above with respect to FIGS. 14 and 18 above. Generally, a first dielectric layer 1404 is formed over a first semiconductor material 102, and a second dielectric layer 1406 is formed over the first dielectric layer 1404. A recess 1502 is formed in the first dielectric layer 1404 and through the second dielectric layer 1406. A third dielectric layer 1602 is formed conformally in the recess 1502. Dielectric spacers 1702 are formed from the third dielectric layer 1602 along the recess dielectric sidewalls 1504. An opening 1802 is formed through the first dielectric layer 1404 to the monocrystalline surface 120 of the first semiconductor material 102. The opening 202 may be formed using appropriate photolithography and etch processes. A cleaning process may be performed after the photolithography and etch processes.

Referring to FIG. 22, a recess 802a, 802b, 802c (generally referred to as recess 802) is formed through the monocrystalline surface 120 and in the first semiconductor material 102. The recess 802 is formed corresponding to the opening 1802 through the first dielectric layer 1404 and extending laterally outside of the opening 1802 and under the first dielectric layer 1404. The recess 802 may be formed using an etch process as described above with respect to FIGS. 8A, 8B, and 8C. A dry cleaning process may be performed before forming the recess 802.

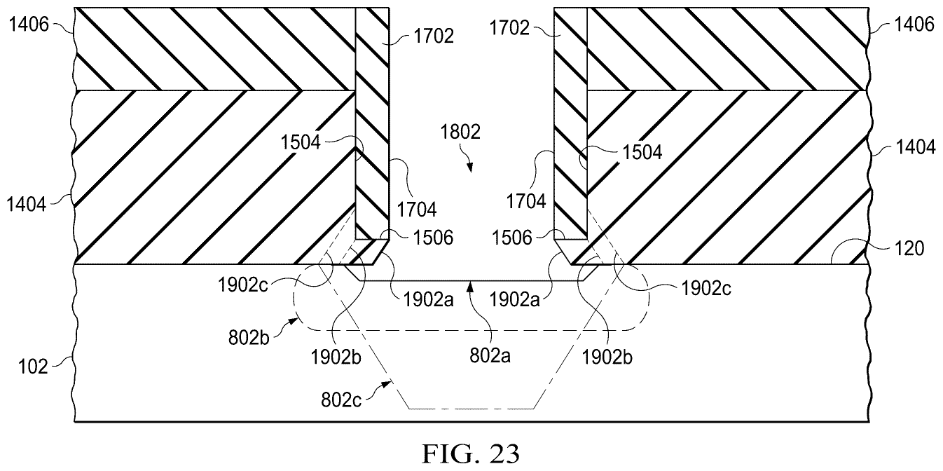

Referring to FIG. 23, a VPE is performed through the opening 1802 as described above with respect to FIG. 19. The VPE selectively etches the first dielectric layer 1404 at the interface between the first dielectric layer 1404 and the first semiconductor material 102. The gradient surface bonding energy permits the VPE to selectively etch the first dielectric layer 1404 at the interface between the first dielectric layer 1404 and the first semiconductor material 102 at a greater rate than etching the first dielectric layer 1404 at the interface between the first dielectric layer 1404 and the dielectric spacers 1702 (e.g., at the recess bottom surface 1506). The VPE forms respective retrograde sidewall portions 1902 (e.g., retrograde sidewall portions 1902a, retrograde sidewall portions 1902b, or retrograde sidewall portions 1902c) in the first dielectric layer 1404 and at the interface between the first dielectric layer 1404 and the first semiconductor material 102. Each retrograde sidewall portion 1902 may be as described above with respect to FIG. 19.

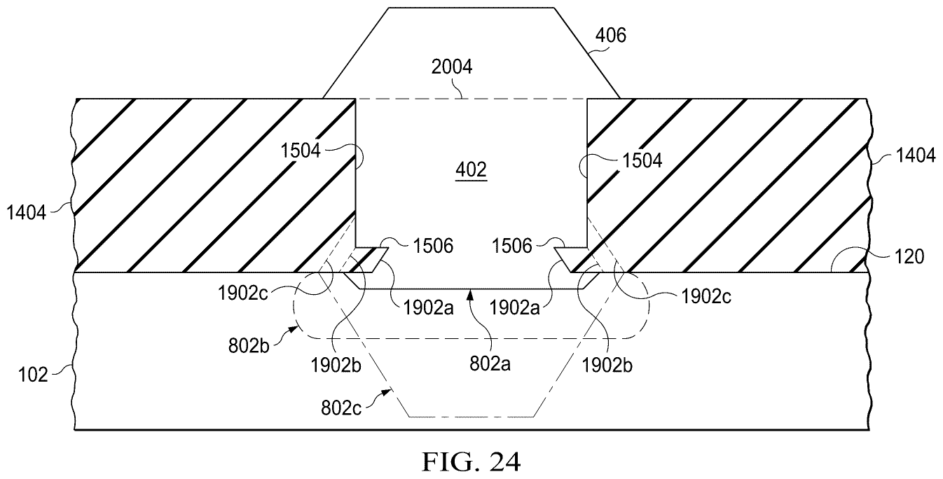

Referring to FIG. 24, the second dielectric layer 1406 is removed. The second dielectric layer 1406 may be removed by any appropriate process, like described above with respect to FIG. 20. A second semiconductor material 402 is epitaxially grown in the opening 1802 and the recess 802 and on the first semiconductor material 102. With the removal of the second dielectric layer 1406 and the dielectric spacers 1702, the opening in which the second semiconductor material 402 is epitaxially grown is defined, at least in part, by the recess dielectric sidewalls 1504, any remaining recess bottom surface 1506, and the retrograde sidewall portions 1902. Before the epitaxial growth, in some examples, a bake process may be performed, like described above.

As described generally previously, in the example of FIG. 24, during the epitaxial growth process, a growth front of the second semiconductor material 402 does not have a facet while the growth front of the second semiconductor material 402 is at or below a level 2004 of an upper surface of the first dielectric layer 1404. When the growth front of the second semiconductor material 402 is above the level 2004 of the upper surface of the first dielectric layer 1404, the second semiconductor material 402 may include an overgrowth portion over the first dielectric layer 1404, and the growth front of the second semiconductor material 402 may include a facet 406. In a manufactured semiconductor device, the upper surface of the second semiconductor material 402 may be below, at, or above the level 2004.

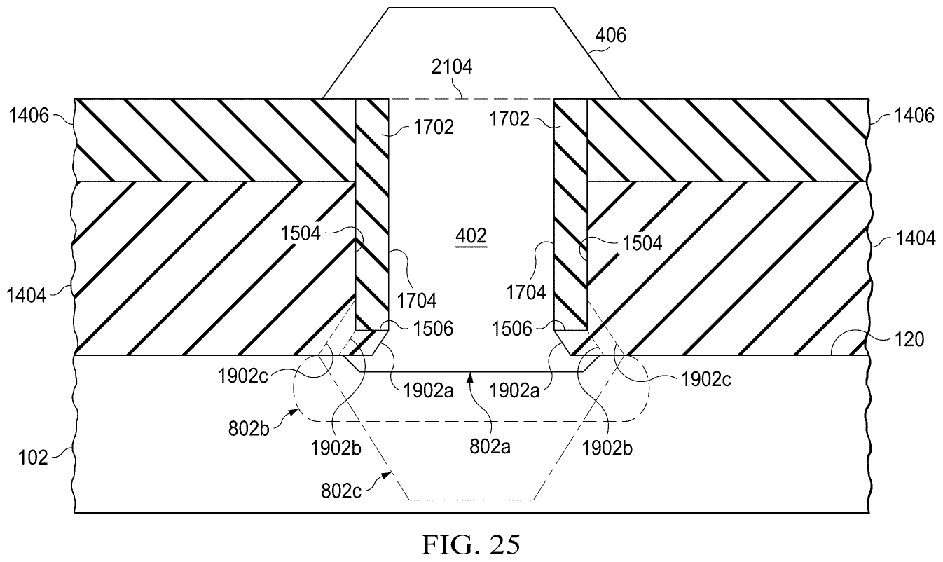

FIG. 25 is a cross-sectional view of a semiconductor structure as a modification to the method of manufacturing in FIGS. 22 through 24 according to some examples. In FIG. 25, the epitaxial growth process to form the second semiconductor material 402 is performed with the second dielectric layer 1406 and dielectric spacers 1702 present. For example, the second dielectric layer 1406 and dielectric spacers 1702 are not removed prior to the epitaxial growth process. The opening in which the second semiconductor material 402 is epitaxially grown is defined, at least in part, by the dielectric sidewalls 1704 of the dielectric spacers 1702 and the retrograde sidewall portions 1902. The bake process and epitaxial growth process may be performed as described above.

In the example of FIG. 25, during the epitaxial growth process, a growth front of the second semiconductor material 402 does not have a facet while the growth front of the second semiconductor material 402 is at or below a level 2104 of an upper surface of the dielectric spacers 1702. When the growth front of the second semiconductor material 402 is above the level 2104 of the upper surface of the dielectric spacers 1702, the second semiconductor material 402 may include an overgrowth portion over the dielectric spacers 1702, and the growth front of the second semiconductor material 402 may include a facet 406. In a manufactured semiconductor device, the upper surface of the second semiconductor material 402 may be below, at, or above the level 2104.

Although various examples have been described in detail, it should be understood that various changes, substitutions, and alterations can be made therein without departing from the scope defined by the appended claims.

What is claimed is:

1. A semiconductor device, comprising:
a first semiconductor material comprising a monocrystalline surface;
a dielectric layer over the first semiconductor material, the dielectric layer having an opening to the first semiconductor material, the opening being defined at least in part by a sidewall of the dielectric layer, the sidewall including a retrograde sidewall portion, the retrograde sidewall portion being planar and retrograde laterally into the dielectric layer from a distance distal from an interface between the dielectric layer and the monocrystalline surface of the first semiconductor material to a surface of the dielectric layer at the interface; and
a second semiconductor material over the first semiconductor material, the second semiconductor material being at least partially in the opening through the dielectric layer.

2. The semiconductor device of claim 1, further comprising a semiconductor substrate comprising the first semiconductor material, the dielectric layer being over the semiconductor substrate.

3. The semiconductor device of claim 1, wherein:
the first semiconductor material includes silicon;
the dielectric layer includes silicon oxide; and
the second semiconductor material includes silicon.

4. The semiconductor device of claim 1, wherein:
the monocrystalline surface of the first semiconductor material has a (100) surface orientation; and
the sidewall of the dielectric layer has a (110) surface orientation.

5. The semiconductor device of claim 1, wherein an overgrowth portion of the second semiconductor material is over an upper surface of the dielectric layer, the overgrowth portion having a facet, the facet having a (111) surface orientation, a (311) surface orientation or a combination thereof.

6. The semiconductor device of claim 1, wherein the first semiconductor material has a recess through the monocrystalline surface, the second semiconductor material being in the recess, the recess extending laterally outside of the opening through the dielectric layer and under the dielectric layer.

7. A method, comprising:
forming a first dielectric layer over a first semiconductor material, the first semiconductor material comprising a monocrystalline surface;
forming an opening through the first dielectric layer to the monocrystalline surface, the opening being defined at least in part by a sidewall of the first dielectric layer;
performing a vapor phase etch, the vapor phase etch etching the first dielectric layer at the sidewall at a surface of the first dielectric layer at a first interface between the first dielectric layer and the monocrystalline surface of the first semiconductor material; and
forming a second semiconductor material over the first semiconductor material and at least partially in the opening through the first dielectric layer.

8. The method of claim 7, wherein the vapor phase etch forms a retrograde sidewall portion of the sidewall of the first dielectric layer, the retrograde sidewall portion being planar and retrograde laterally into the first dielectric layer from a distance distal from the first interface to the surface of the first dielectric layer at the first interface.

9. The method of claim 7, further comprising forming a second dielectric layer over the first dielectric layer before forming the opening, the opening further being through the second dielectric layer, the vapor phase etch being performed through the opening formed through the second dielectric layer.

10. The method of claim 9, wherein the first dielectric layer includes silicon oxide, and the second dielectric layer includes silicon nitride.

11. The method of claim 9, wherein the first interface has a first surface bonding energy, a second interface between the first dielectric layer and the second dielectric layer has a second surface bonding energy, the first surface bonding energy being different from the second surface bonding energy.

12. The method of claim 7, wherein forming the opening includes:
forming a recess in the first dielectric layer, the recess being defined at least in part by a recess sidewall of the first dielectric layer;
forming a second dielectric layer conformally in the recess;
etching the second dielectric layer at a bottom of the recess, wherein a sidewall spacer formed from the second dielectric layer remains along the recess sidewall; and
etching the first dielectric layer through the bottom of the recess to form the opening, wherein the vapor phase etch is performed through the opening with the sidewall spacer along the recess sidewall of the recess.

13. The method of claim 12, wherein the first dielectric layer includes silicon oxide, and the second dielectric layer includes silicon nitride.

14. The method of claim 12, wherein the first interface has a first surface bonding energy, a second interface between the first dielectric layer and the sidewall spacer has a second surface bonding energy, the first surface bonding energy being different from the second surface bonding energy.

15. The method of claim 7, wherein:
the monocrystalline surface of the first semiconductor material has a (100) surface orientation; and
the sidewall of the first dielectric layer has a (110) surface orientation.

16. The method of claim 7, further comprising etching the first semiconductor material through the opening, etching the first semiconductor material undercutting the first semiconductor material under the first dielectric layer.

17. A semiconductor device, comprising:
a first semiconductor material comprising a monocrystalline surface;
a dielectric layer over the first semiconductor material, the dielectric layer having an opening to the first semiconductor material, the opening being to a recess in the first semiconductor material, the recess being through the monocrystalline surface and undercutting the dielectric layer; and
a second semiconductor material over the first semiconductor material and in the recess, the second semiconductor material being at least partially in the opening through the dielectric layer.

18. The semiconductor device of claim 17, further comprising a semiconductor substrate comprising the first semiconductor material, the dielectric layer being over the semiconductor substrate.

19. The semiconductor device of claim 17, wherein:
the first semiconductor material includes silicon;
the dielectric layer includes silicon oxide; and
the second semiconductor material includes silicon.

20. The semiconductor device of claim 17, wherein:
the monocrystalline surface of the first semiconductor material has a (100) surface orientation; and
the opening is defined at least in part by a sidewall of the dielectric layer, the sidewall of the dielectric layer having a (110) surface orientation.

21. The semiconductor device of claim 17, wherein an overgrowth portion of the second semiconductor material is over an upper surface of the dielectric layer, the overgrowth portion having a facet, the facet having a (111) surface orientation, a (311) surface orientation, or a combination thereof.

22. The semiconductor device of claim 17, wherein the opening is defined at least in part by a sidewall of the dielectric layer, the sidewall including a retrograde sidewall portion, the retrograde sidewall portion being planar and retrograde laterally into the dielectric layer from a distance distal from an interface between the dielectric layer and the monocrystalline surface of the first semiconductor material to a surface of the dielectric layer at the interface.

23. A method, comprising:
forming a dielectric layer over a first semiconductor material, the first semiconductor material comprising a monocrystalline surface;
forming an opening through the dielectric layer to the monocrystalline surface, the opening being defined at least in part by a sidewall of the dielectric layer;
forming a recess in the first semiconductor material through the monocrystalline surface, forming the recess being through the opening through the dielectric layer, the recess in the first semiconductor material undercutting the dielectric layer; and
forming a second semiconductor material over the first semiconductor material, the second semiconductor material being in the recess in the first semiconductor material and at least partially in the opening through the dielectric layer.

24. The method of claim 23, wherein forming the recess includes performing an isotropic etch.

25. The method of claim 23, wherein forming the recess includes performing an anisotropic etch.

26. The method of claim 23, wherein forming the recess includes performing a dry etch.

27. The method of claim 23, wherein forming the recess includes performing a wet etch.

28. The method of claim 23, wherein forming the recess includes performing an etch using a plasma.

29. The method of claim 23, wherein forming the recess includes performing an etch without a plasma.

30. The method of claim 23, wherein forming the recess includes performing an etch using an etchant comprising hydrochloric acid (HCl).

31. The method of claim 23, wherein forming the recess includes performing an etch using an etchant comprising hydrobromic acid (HBr).

32. The method of claim 23, wherein forming the recess includes performing an etch using an etchant comprising chlorine (Cl₂).

33. The method of claim 23, wherein forming the recess includes performing an etch using an etchant comprising bromine (Br₂).

34. The method of claim 23, further comprising performing a vapor phase etch, the vapor phase etch etching the dielectric layer to form a retrograde sidewall portion of the sidewall of the dielectric layer, the sidewall defining at least a portion of the opening, the retrograde sidewall portion being planar and retrograde laterally into the dielectric layer from a distance distal from an interface between the dielectric layer and the monocrystalline surface of the first semiconductor material to a surface of the dielectric layer at the interface.

35. The method of claim 23, wherein:
the monocrystalline surface of the first semiconductor material has a (100) surface orientation; and
the sidewall of the dielectric layer has a (110) surface orientation.
